(19) United States
(12) Patent Application Publication
(10) Pub. No.: US 2011/0111593 A1
(43) Pub. Date: May 12, 2011

(54) PATTERN FORMATION METHOD, PATTERN FORMATION SYSTEM, AND METHOD FOR MANUFACTURING SEMICONDUCTOR DEVICE

(76) Inventor: Masahiro KANNO, Kanagawa-ken (JP)

(21) Appl. No.: 12/884,796

(22) Filed: Sep. 17, 2010

(30) Foreign Application Priority Data
Nov. 9, 2009 (JP) 2009-256032

(51) Int. Cl. H01L 21/302; H01L 21/308

(52) U.S. Cl. 438/689; 216/40; 156/345.3; 156/345.24; 257/E21.214

(57) ABSTRACT

According to one embodiment, a pattern formation method is disclosed. The method can form a patterning film on a substrate. The method can transfer a form pattern provided on a template onto an imprint material by bringing the template into contact with the imprint material. The imprint material is coated on the patterning film. In addition, the method can perform patterning including etching the patterning film using the imprint material including the transferred form pattern as a mask. The transferring is implemented using a condition determined based on data relating to at least one selected from a dimension and a shape of a pattern of the patterning film after the patterning.

### CROSS-REFERENCE TO RELATED APPLICATIONS

This application is based upon and claims the benefit of priority from the prior Japanese Patent Application No. 2009-256032, filed on Nov. 9, 2009; the entire contents of which are incorporated herein by reference.

### FIELD

Embodiments described herein relate generally to a pattern formation method, a pattern formation system, and a method for manufacturing a semiconductor device.

### BACKGROUND

Nanoimprinting used to transfer a master form onto a substrate is drawing attention as a technology to form ultra-fine patterns with high productivity when manufacturing electronic devices having ultra-fine structures such as semiconductor devices, MEMS (Micro Electro Mechanical System) devices, etc.

In nanoimprinting, a pattern is transferred onto a resin on the substrate by pressing the master form (the template) having the pattern to be transferred onto a resin on the substrate and by curing the resin.

JP-A 2007-73939 (Kokai) discusses a method for increasing the transfer precision by controlling the positional relationship between a form and a substrate and controlling the light irradiation amount based on measurement information from measuring a physical quantity of the state of a resin occurring due to light irradiation in the case where a photocurable resin is used.

However, even in the case where the pattern of the resin after the transferring is controlled to the desired configuration when patterning the patterning film using the resin including the transferred form as a mask, effects of other processes may cause the pattern dimension and the pattern shape of the patterning film after the patterning to not have the desired values (states) which may impede performance improvement and downscaling of the electronic device and may lead to decreased yields and the like that reduce the productivity.

### BRIEF DESCRIPTION OF THE DRAWINGS

FIG. 1 is a flowchart illustrating a pattern formation method according to a first embodiment;

FIG. 2 is a schematic view illustrating a pattern formation system using the pattern formation method according to the first embodiment;

FIG. 3 is a schematic perspective view illustrating a coordinate system of the pattern formation method according to the first embodiment;

FIGS. 4A to 4E are schematic cross-sectional views in order of the processes, illustrating the pattern formation method according to the first embodiment;

FIGS. 5A to 5E are graphs illustrating the pattern formation method according to the first embodiment;

FIGS. 6A to 6C are graphs illustrating a pattern formation method of a comparative example;

FIG. 7 is a schematic plan view illustrating the pattern formation method according to the first embodiment;

FIG. 8 is a schematic plan view illustrating the pattern formation method according to the first embodiment;

FIGS. 9A and 9B are schematic views illustrating the pattern formation method according to the first embodiment;

FIG. 10 is a flowchart illustrating one other pattern formation method according to the first embodiment;

FIG. 11 is a flowchart illustrating yet one other pattern formation method according to the first embodiment; and

FIG. 12 is a flowchart illustrating a pattern formation method according to a second embodiment.

### DETAILED DESCRIPTION

In general, according to one embodiment, a pattern formation method is disclosed. The method can form a patterning film on a substrate. The method can transfer a form pattern provided on a template onto an imprint material by bringing the template into contact with the imprint material. The imprint material is coated on the patterning film. In addition, the method can perform patterning including etching the patterning film using the imprint material including the transferred form pattern as a mask. The transferring is implemented using a condition determined based on data relating to at least one selected from a dimension and a shape of a pattern of the patterning film after the patterning.

According to another embodiment, a pattern formation system includes a transfer unit, a patterning unit, and a data storage unit. The transfer unit transfers a form pattern of a template onto an imprint material by bringing the template into contact with the imprint material. The imprint material is coated on a patterning film of a substrate. The patterning unit performs patterning including etching the patterning film using the imprint material including the transferred form pattern as a mask. The data storage unit stores data relating to at least one selected from a dimension and a shape of a pattern of the patterning film after the patterning. At least one portion of a condition of processing of the transfer unit is determined based on the data stored in the data storage unit.

According to yet another embodiment, a method is disclosed for manufacturing a semiconductor device. The method can form a patterning film on a substrate. At least one selected from the substrate and the patterning film includes a semiconductor. The method can transfer a form pattern provided on a template onto an imprint material by bringing the template into contact with the imprint material. The imprint material is coated on the patterning film. In addition, the method can perform patterning including etching of the patterning film using the imprint material including the transferred form pattern as a mask. The transferring is implemented using a condition determined based on data relating to at least one selected from a dimension and a shape of a pattern of the patterning film after the patterning.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Further, the dimensions and proportional coefficients may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

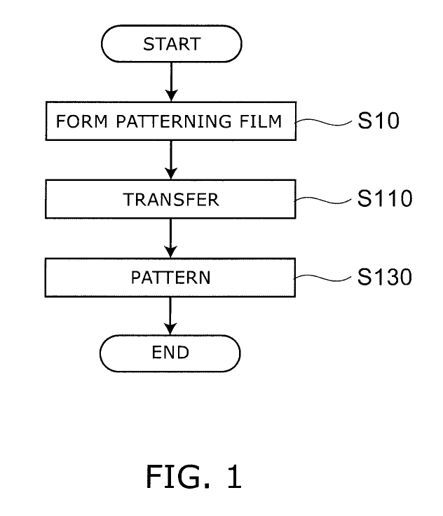

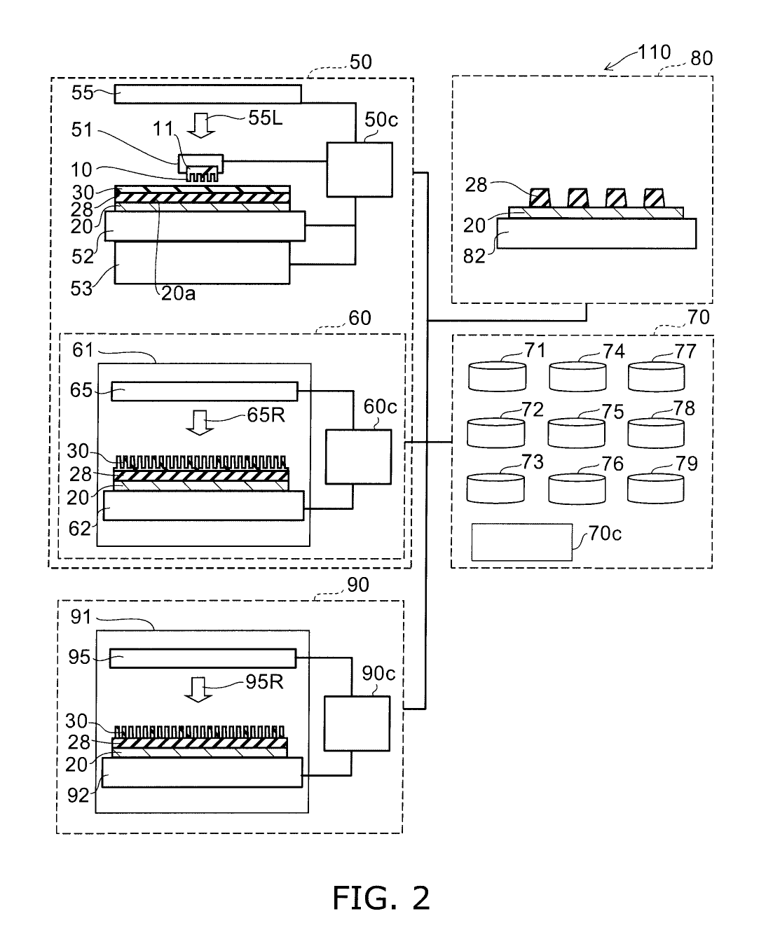

FIG. 1 is a flowchart illustrating a pattern formation method according to a first embodiment. FIG. 2 is a schematic view illustrating the configuration of a pattern formation system using the pattern formation method according to the first embodiment.

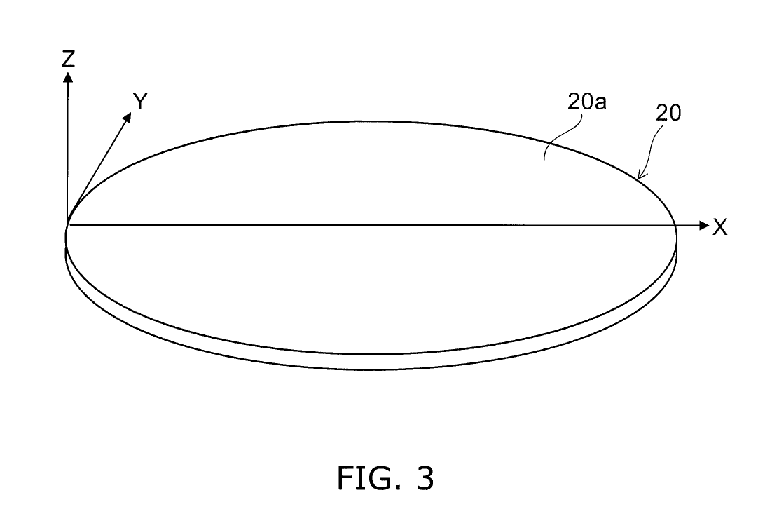

FIG. 3 is a schematic perspective view illustrating a coordinate system of the pattern formation method according to the first embodiment.

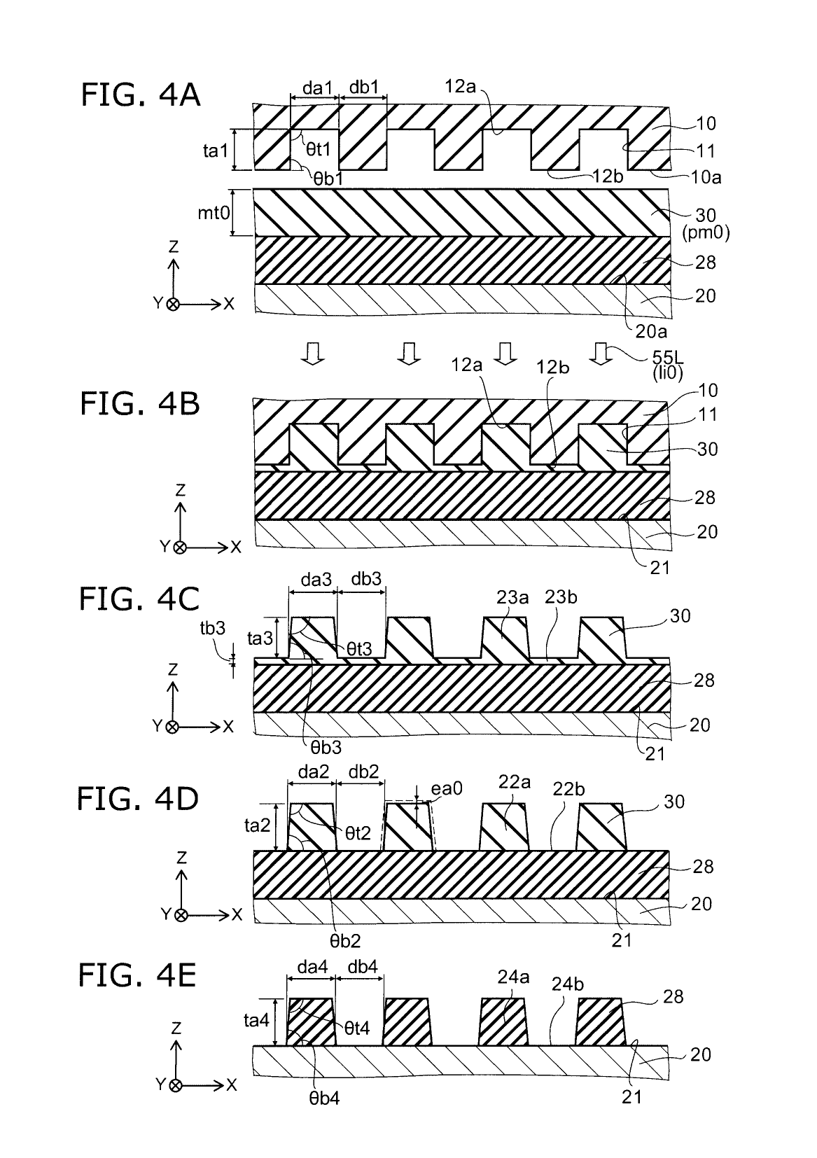

FIGS. 4A to 4E are schematic cross-sectional views in order of the processes, illustrating the pattern formation method according to the first embodiment.

First, an overview of the configuration of the pattern formation system used in the pattern formation method according to this embodiment will be described using FIG. 2.

As illustrated in FIG. 2, the pattern formation system 110 according to this embodiment includes a transfer unit 50, a patterning unit 90, and a data storage unit 70. As described below, the transfer unit 50 may include a post-processing unit 60.

The transfer unit 50 brings a template 10 into contact with an imprint material 30 coated on a patterning film 28 on a major surface 20a of a substrate 20 to transfer a form pattern 11 provided on the template 10 onto the imprint material 30.

In this specific example, the transfer unit 50 includes: a template holder 51 that holds the template 10; a transfer unit stage 52 on which the substrate 20 is placed; a drive unit 53 that brings the template 10 into contact with the imprint material 30 by changing the distance between the template 10 and the substrate 20; an irradiation unit 55 that irradiates light 55L onto the imprint material 30; and a transfer control unit 50c that controls the template holder 51, the transfer unit stage 52, the drive unit 53, and the irradiation unit 55.

Although the drive unit 53 is mounted to the transfer unit stage 52 in this specific example, the drive unit may be mounted to the template holder 51; or drive units may be provided on each of the transfer unit stage 52 and the template holder 51 to drive both the transfer unit stage 52 and the template holder 51.

In this specific example, the template 10 may include a substrate (a base member) such as, for example, quartz having the form pattern 11 provided on the surface.

The substrate 20 may include, for example, a semiconductor substrate (a wafer) or a substrate including at least one selected from a semiconductor layer, a conductive layer, and an insulating layer. The patterning film 28 may include at least one selected from a semiconductor layer, a conductive layer, and an insulating layer. The patterning film 28 may be a stacked film of multiple films such as semiconductor layers, conductive layers, and insulating layers. Thus, the substrate 20 may include various substrates (wafers) on which the patterning film 28 is provided, etc. Processing of various patterning using the imprint material as a mask is performed on the patterning film 28.

The imprint material 30 may include, for example, various resins. In this specific example, a photocurable resin is used. The imprint material 30 may include a thermosetting resin.

As described below, the post-processing unit 60 performs post-processing to expose a portion of the patterning film by removing the residual film of the imprint material 30 including the transferred form pattern 11, where the residual film is a portion of the imprint material 30 between the patterning film 28 and a protrusion of the form pattern 11. In this specific example, the post-processing unit 60 is included in the transfer unit 50. The post-processing unit 60 is provided as necessary; and the post-processing unit 60 may be omitted.

In this specific example, the post-processing unit 60 includes: a post-processing unit stage 62 on which the substrate 20 is placed; a post-processing chamber 61 (a chamber) that stores the post-processing unit stage 62 and the substrate 20; a post-processing etchant supply unit 65 that supplies a post-processing etchant 65R into the post-processing chamber 61 to etch the imprint material 30; and a post-processing control unit 60c that controls the post-processing unit stage 62 and the post-processing etchant supply unit 65.

In other words, in this specific example, the post-processing unit 60 is a dry etching apparatus performing etch-back of the imprint material 30; the post-processing etchant 65R is, for example, a gas in a high energy state including radicals and the like; and the post-processing etchant supply unit 65 may include a plasma generation unit and a gas supply unit.

The patterning unit 90 etches the patterning film 28 using the imprint material 30 including the transferred form pattern 11 as a mask. However, the patterning unit 90 may perform patterning other than such etching. In other words, the patterning unit 90 performs patterning including etching the patterning film 28 using the imprint material 30 including the transferred form pattern 11 as a mask.

In this specific example, the patterning unit 90 includes: a patterning unit stage 92 on which the substrate 20 is placed; a patterning processing chamber 91 (a chamber) that stores the patterning unit stage 92 and the substrate 20; a patterning etchant supply unit 95 that supplies a patterning etchant 95R into the patterning processing chamber 91 to etch the patterning film 28; and a patterning control unit 90c that controls the patterning unit stage 92 and the patterning etchant supply unit 95.

In other words, in this specific example, the patterning unit 90 is a dry etching apparatus that etches the patterning film 28; the patterning etchant 95R is, for example, a gas in a high energy state including radicals and the like; and the patterning etchant supply unit 95 may include a plasma generation unit and a gas supply unit.

In some cases, the post-processing unit 60 and the patterning unit 90 may be combined. In such a case, the post-processing unit 60 is not provided; and the patterning unit 90 performs the functions of the post-processing unit 60.

The data storage unit 70 stores data relating to at least one selected from the dimension and the shape of the pattern of the patterning film 28 after the patterning (after the etching). In this specific example, first to ninth data storage units 71 to 79 are provided in the data storage unit 70. The data storage unit 70 may store data relating to at least one selected from the dimension and the shape of the pattern of the imprint material 30 after the transfer process and the pattern dimension and shape of the imprint material 30 after the post-processing.

The pattern formation system 110 may further include a measurement unit 80. The measurement unit 80 measures at least one selected from the dimension and the shape of the pattern of the patterning film 28 after the patterning.

The measurement unit 80 may include a measuring device that measures various ultra-fine configurations such as, for example, an AFM (atomic force microscope), a SEM (scanning electron microscope), etc. For example, the measurement unit 80 includes a measurement unit stage 82; the substrate 20 is placed on the measurement unit stage 82; and at least one selected from the dimension and the shape of the pattern of the patterning film 28 is measured. The patterning film 28 may be measured in a non-destructive state; and the patterning film 28 may be divided and the measuring may be performed on the patterning film 28 of a partial region. The measurement unit 80 may further measure at least one selected from the dimension and the shape of the pattern of the imprint material 30 after the transfer process and the pattern dimension and shape of the imprint material 30 after the post-processing.

It is not always necessary for the transfer unit 50 (including the post-processing unit 60), the patterning unit 90, the data storage unit 70, and the measurement unit 80 to be juxtaposed with each other. The transfer unit 50 (including the post-processing unit 60), the patterning unit 90, the data storage unit 70, and the measurement unit 80 may be disposed in separate locations in a configuration in which data can be transferred therebetween.

The transferring of the data between the transfer unit 50 (including the post-processing unit 60), the patterning unit 90, the data storage unit 70, and the measurement unit 80 can be performed by methods using various wired and wireless communication methods and various data storage media.

An XYZ orthogonal coordinate system will now be introduced for convenience of description.

Namely, as illustrated in FIG. 3, a direction perpendicular to the major surface 20a of the substrate 20 is taken as a Z axis direction. One direction in the plane parallel to the major surface 20a is taken as an X axis direction. A direction perpendicular to the Z axis direction and the X axis direction is taken as a Y axis direction.

Using FIGS. 4A to 4E, the pattern formation method according to this embodiment, that is, operations of the pattern formation system 110 according to this embodiment, will now be described.

As illustrated in FIG. 4A, the imprint material 30 is coated on the patterning film 28 on the major surface 20a of the substrate 20. The form pattern 11 is provided on a major surface 10a of the template 10.

The form pattern 11 includes a form recess 12a and a form protrusion 12b. In other words, the form pattern 11 having recesses and protrusions is provided on the major surface 10a (the transfer surface) on the side of the template 10 opposing the substrate 20 (the patterning film 28). The major surface 10a of the template 10 and the major surface 20a of the substrate 20 may be disposed parallel to each other. The major surface 10a of the template 10 is parallel to the X-Y plane and is perpendicular to the Z axis direction.

The planar configurations (the pattern configurations as viewed from the Z axis direction) of the form recess 12a and the form protrusion 12b are arbitrary and may be, for example, trench configurations aligned in one direction, rectangular or square configurations, flattened circular configurations or circular configurations, and any polygonal shape.

A form depth ta1 is taken as the depth of the form recess 12a of the form pattern 11. The form depth ta1 is the distance along the direction (the Z axis direction) perpendicular to the major surface 10a from the bottom portion of the form recess 12a (the portion of the form recess 12a on the side opposite to the substrate 20) to the apical portion of the form protrusion 12b (the portion of the form protrusion 12b on the substrate 20 side).

A form recess width da1 is taken as the width of the form recess 12a; and a form protrusion width db1 is taken as the width of the form protrusion 12b. The form recess width da1 and the form protrusion width db1 are the lengths of the form recess 12a and the form protrusion 12b, respectively, along one direction in the X-Y plane.

To simplify the description hereinbelow, attention is focused on the X axis direction. In other words, the form recess width da1 and the form protrusion width db1 are the lengths of the form recess 12a and the form protrusion 12b, respectively, along the X axis direction. Although the description hereinbelow relates to the X axis direction, the description similarly relates to the Y axis direction, and similar effects are obtained by applying the embodiments.

The form recess width da1 and the form protrusion width db1 are taken as the widths of the form recess 12a and the form protrusion 12b, respectively, at intermediate positions of the depth of the form recess 12a in the Z axis direction. In other words, the side wall of the form recess 12a and the form protrusion 12b is not necessarily parallel to the Z axis direction. For example, the side wall may be an oblique face having a tapered configuration inclined with respect to the Z axis direction. In such a case as well, the form recess width da1 and the form protrusion width db1 are defined as widths at positions of the intermediate points of the recesses and protrusions of the form recess 12a and the form protrusion 12b.

A form bottom angle θt1 is taken as the angle between the bottom portion of the form recess 12a and the side wall of the form recess 12a. A form apical angle θb1 is taken as the angle between the apical portion of the form protrusion 12b and the side wall of the form recess 12a.

As described above, the side wall of the form recess 12a and the form protrusion 12b may be an oblique face having a tapered configuration. In such a case, the form bottom angle θt1 and the form apical angle θb1 are angles different from 90 degrees. In the case where the side wall of the form recess 12a and the form protrusion 12b is a perpendicular wall, the form bottom angle θt1 and the form apical angle θb1 are 90 degrees.

The template 10 having such a form pattern 11 is disposed to oppose the imprint material 30 coated on the patterning film 28 of the major surface 20a of the substrate 20.

An imprint material thickness mt0 is the thickness of the coated imprint material 30. It is not always necessary for the imprint material 30 to be coated on the patterning film 28 with a uniform thickness. For example, the imprint material 30 may be coated on the patterning film 28 in liquid droplets disposed at a prescribed spacing. In such a case, the imprint material thickness mt0 may be taken as the average thickness of the imprint material 30. For example, the imprint material thickness mt0 may be taken as an amount corresponding to the coating amount of the imprint material 30 (e.g., the volume of the imprint material 30 per unit surface area). A material pm0 is used as the imprint material 30.

Then, as illustrated in FIG. 4B, the distance between the template 10 and the imprint material 30 is reduced; and the template 10 and the imprint material 30 contact each other. Thereby, a portion of the imprint material 30 enters the form recess 12a of the form pattern 11. In other words, for example, quartz and the like is used as the template 10; a photocurable resin and the like is used as the imprint material 30; the imprint material 30 deforms more easily than the template 10; and a portion of the imprint material 30 enters the form recess 12a of the form pattern 11 when the template 10 and the imprint material 30 are pressed together. In the case where the viscosity of the imprint material 30 is low, the imprint material 30 enters the interior of the form recess 12a of the form pattern 11 by, for example, capillary action when the template 10 and the imprint material 30 contact each other; and the interior of the form recess 12a is filled with the imprint material 30. Thereby, the imprint material 30 deforms to conform to the configuration of the form recess 12a and the form protrusion 12b of the form pattern 11.

In such a state, the light 55L (that cures the imprint material 30, e.g., an ultraviolet ray) is irradiated onto the imprint material 30 to cure the imprint material 30. In the case where the imprint material 30 is a thermosetting resin, the imprint material 30 is heated. A light irradiation amount li0 is taken as the irradiation energy of the light 55L.

Subsequently, the template 10 and the imprint material 30 (the substrate 20) are separated from each other.

Thereby, as illustrated in FIG. 4C, the form pattern 11 provided on the template 10 can be transferred onto the imprint material 30 coated on the patterning film 28 on the major surface 20a of the substrate 20 by bringing the form pattern 11 into contact with the imprint material 30.

In other words, a post-transfer protrusion 23a is formed corresponding to the form recess 12a in the imprint material 30; and a post-transfer recess 23b is formed corresponding to the form protrusion 12b in the imprint material 30.

In some cases during the processes recited above, the form protrusion 12b and the patterning film 28 may not completely contact each other; and the imprint material 30 may exist between the form protrusion 12b and the patterning film 28. Such a portion forms a residual film when the imprint material 30 is cured in such a state. In other words, the portion of the imprint material 30 including the transferred form pattern 11 between the patterning film 28 and a protrusion (the form protrusion 12b) of the form pattern 11 forms a residual film. For example, the template 10 and the substrate 20 are pressed together in a state of the template 10 contacting the imprint material 30; and the degree of the imprint material 30 flowing outside the major surface 10a of the template 10 and the distance between the template 10 and the patterning film 28 change with the degree of the pressing. The thickness of the residual film changes as a result of curing the imprint material 30 in such a state. Thus, in some cases, the residual film may be formed. FIGS. 4B and 4C illustrate an example in which the residual film is formed. The residual film may not be formed.

Herein, a post-transfer recess thickness tb3 is taken as the thickness (the length along the Z axis direction) of the post-transfer recess 23b. A post-transfer protrusion height ta3 is taken as the height of the post-transfer protrusion 23a as viewed from the post-transfer recess 23b. In other words, the thickness (the length along the Z axis direction) of the post-transfer protrusion 23a is the total of the post-transfer recess thickness tb3 and the post-transfer protrusion height ta3. The thickness of the residual film corresponds to the post-transfer recess thickness tb3 recited above.

A post-transfer protrusion width da3 is taken as the width of the post-transfer protrusion 23a along the X axis direction; and a post-transfer recess width db3 is taken as the width of the post-transfer recess 23b along the X axis direction. In such a case as well, the post-transfer protrusion width da3 and the post-transfer recess width db3 may be taken as the widths of the post-transfer protrusion 23a and the post-transfer recess 23b at intermediate positions of the post-transfer protrusion height ta3 in the Z axis direction.

A post-transfer protrusion angle θt3 is taken as the angle between the apical portion of the post-transfer protrusion 23a and the side wall of the post-transfer protrusion 23a; and a post-transfer bottom angle θb3 is taken as the angle between the bottom portion of the post-transfer protrusion 23a and the side wall of the post-transfer protrusion 23a.

Ideally, the post-transfer protrusion height ta3 matches the form depth ta1, the post-transfer protrusion width da3 matches the form recess width da1, the post-transfer recess width db3 matches the form protrusion width db1, the post-transfer protrusion angle θt3 matches the form bottom angle θt1, and the post-transfer bottom angle θb3 matches the form apical angle θb1. However, due to characteristics such as the contraction of the imprint material 30, the deformation of the substrate 20 (including the patterning film 28) and the template 10, etc., the post-transfer protrusion height ta3 does not always match the form depth ta1, the post-transfer protrusion width da3 does not always match the form recess width da1, the post-transfer recess width db3 does not always match the form protrusion width db1, the post-transfer protrusion angle θt3 does not always match the form bottom angle θt1, and the post-transfer bottom angle θb3 does not always match the form apical angle θb1.

Subsequently, in the case where the residual film is formed, a portion of the patterning film 28 of the major surface 20a of the substrate 20 is exposed by etching the post-transfer recess 23b of the imprint material 30 as illustrated in FIG. 4D. For example, etching is performed on the entire surface of the imprint material 30 and etch-back of both the post-transfer protrusion 23a and the post-transfer recess 23b is performed simultaneously until the post-transfer recess 23b is removed. In other words, a post-processing is performed to expose a portion of the patterning film 28 of the major surface 20a of the substrate 20 by reducing the film thickness of the imprint material 30 after the transferring.

In other words, the film thickness of the post-transfer protrusion 23a is reduced to form a post post-processing protrusion 22a. A post post-processing recess 22b is formed between the post post-processing protrusions 22a. A post post-processing protrusion height ta2 is taken as the height (the length along the Z axis direction) of the post post-processing protrusion 22a.

The post post-processing protrusion height ta2 has a value of, for example, the post-transfer protrusion height ta3 minus the post-transfer recess thickness tb3. However, considering the margin of the etching recited above, the post post-processing protrusion height ta2 has a value slightly less than, for example, the value of the post-transfer protrusion height ta3 minus the post-transfer recess thickness tb3.

The reduction amount of the film thickness of the imprint material 30, i.e., an etching amount ea0 (the post-transfer recess thickness tb3 plus the margin) is, for example, the post-transfer protrusion height ta3 plus the post-transfer recess thickness tb3 minus the post post-processing protrusion height ta2.

A post post-processing protrusion width da2 is taken as the width of the post post-processing protrusion 22a along the X axis direction; and a post post-processing recess width db2 is taken as the width of the post post-processing recess 22b along the X axis direction. In such a case as well, the post post-processing protrusion width da2 and the post post-processing recess width db2 may be taken as the widths of the post post-processing protrusion 22a and the post post-processing recess 22b at intermediate positions of the post post-processing protrusion height ta2 in the Z axis direction.

In the case where the etching is isotropic, the post post-processing protrusion width da2 has a value of, for example, the post-transfer protrusion width da3 minus twice the thickness of the post-transfer recess thickness tb3. However, considering the margin of the etching of the post-processing, such a value is further reduced by twice the thickness of the margin of the etching. Similarly, the post post-processing recess width db2 has a value of the post-transfer recess width db3 plus twice the thickness of the post-transfer recess thickness tb3. Considering the margin of the etching of the post-processing, such a value is further increased by twice the thickness of the margin of the etching.

A post post-processing apical angle θt2 is taken as the angle between the apical portion of the post post-processing protrusion 22a and the side wall of the post post-processing protrusion 22a; and a post post-processing bottom angle θb2 is taken as the angle between the bottom portion of the post post-processing protrusion 22a and the side wall of the post post-processing protrusion 22a. Here, due to characteristics of the post-processing, the post post-processing apical angle θt2 does not always match the post-transfer protrusion angle θt3, and the post post-processing bottom angle θb2 does not always match the post-transfer bottom angle θb3.

At least one selected from the post post-processing protrusion height ta2, the post post-processing protrusion width da2, the post post-processing recess width db2, the post post-processing apical angle θt2, and the post post-processing bottom angle θb2 may fluctuate in the surface (the X-Y plane) of the substrate 20 due to, for example, the fluctuation of characteristics in the X-Y plane during the post-processing; and the dimension and the shape of the imprint material 30 after the post-processing may not have the desired configurations.

The processes illustrated in FIGS. 4A to 4C correspond to the transfer and template separation process of transferring the form pattern 11 provided on the template 10 onto the imprint material 30 coated on the patterning film 28 on the major surface 20a of the substrate 20 by bringing the form pattern 11 into contact with the imprint material 30. The process illustrated in FIG. 4D corresponds to the post-processing process of exposing a portion of the patterning film 28 by removing the residual film of the imprint material 30 including the transferred form pattern 11, where the residual film is a portion of the imprint material 30 between the patterning film 28 and a protrusion (the form protrusion 12b) of the form pattern 11. Step S110 illustrated in FIG. 1 includes the transfer and template separation process recited above. In the case where the post-processing is performed, step S110 further includes the post-processing process.

Subsequently, as illustrated in FIG. 4E, the patterning film 28 is etched after the post-processing using the imprint material 30 as a mask. Such a process corresponds to step S130 illustrated in FIG. 1.

A substrate protrusion 24a and a substrate recess 24b are formed in the substrate 20 by etching the patterning film 28 using the imprint material 30 as a mask. In other words, the portion where a portion of the patterning film 28 is removed becomes the substrate recess 24b; and the portion where the patterning film 28 remains (the portion having a thickness thicker than the substrate recess 24b by the thickness of the patterning film 28) becomes the substrate protrusion 24a. In other words, the substrate recess 24b is disposed between the substrate protrusions 24a. A substrate protrusion height ta4 is taken as the height (the length along the Z axis direction) of the substrate protrusion 24a. Although the entire thickness of the portion of the patterning film 28 not covered with the imprint material 30 is removed in this specific example, the portion of the patterning film 28 not covered with the imprint material 30 may be removed partway through the thickness of the patterning film 28.

The etching amount of the patterning film 28 may be determined appropriately according to the desired value of the difference of the height between the substrate protrusion 24a and the substrate recess 24b to be formed in the substrate 20.

A substrate protrusion width da4 is taken as the width of the substrate protrusion 24a along the X axis direction; and a substrate recess width db4 is taken as the width of the substrate recess 24b along the X axis direction. In such a case as well, the substrate protrusion width da4 and the substrate recess width db4 may be taken as the widths of the substrate protrusion 24a and the substrate recess 24b at, for example, an intermediate position of the substrate protrusion height ta4 in the Z axis direction.

A substrate apical angle θt4 is taken as the angle between the apical portion of the substrate protrusion 24a and the side wall of the substrate protrusion 24a; and a substrate bottom angle θb4 is taken as the angle between the bottom portion of the substrate protrusion 24a and the side wall of the substrate protrusion 24a.

In some cases, at least one selected from the substrate protrusion height ta4, the substrate protrusion width da4, the substrate recess width db4, the substrate apical angle θt4, and the substrate bottom angle θb4 of the substrate 20 after the patterning does not have the desired value. For example, such a value may fluctuate in the X-Y plane.

For example, even in the case where the pattern configuration of the imprint material 30 after the post-processing is uniform in the X-Y plane, at least one selected from the substrate protrusion height ta4, the substrate protrusion width da4, the substrate recess width db4, the substrate apical angle θt4, and the substrate bottom angle θb4 may fluctuate in the surface (the X-Y plane) of the substrate 20 due to the fluctuation of the characteristics in the X-Y plane during the patterning process.

In the pattern formation method and the pattern formation system according to this embodiment, a condition of the transfer process is set such that the dimension and the shape of the pattern after the patterning process have the desired values by also considering the characteristics of the patterning process.

In other words, as illustrated in FIG. 1, the pattern formation method according to this embodiment includes: forming the patterning film 28 on the substrate 20 (step S10); transferring the form pattern 11 provided on the template 10 onto the imprint material 30 coated on the patterning film 28 by bringing the template 10 into contact with the imprint material 30 (step S110); and performing patterning including etching the patterning film 28 using the imprint material 30 including the transferred form pattern as a mask (step S130).

The transfer process is implemented using a condition determined based on data relating to at least one selected from the dimension and the shape of the pattern of the patterning film 28 after the patterning.

In other words, in the pattern formation system 110, at least one portion of the condition of the processing of the transfer unit 50 is determined based on data (data relating to at least one selected from the dimension and the shape of the pattern of the patterning film 28 after the patterning) stored in the data storage unit 70.

Herein, the dimension of the pattern of the patterning film 28 after the patterning includes at least one selected from the substrate protrusion height ta4, the substrate protrusion width da4, and the substrate recess width db4. The shape of the pattern of the patterning film 28 after the patterning includes at least one selected from the substrate apical angle θt4 and the substrate bottom angle eb4.

Thereby, by also considering the patterning process after the transfer process, the pattern dimension and the pattern shape after the patterning can have the desired values. Thereby, performance improvement and downscaling of electronic devices (including semiconductor devices) manufactured using the pattern formation method and the pattern formation system 110 are easy; the yields can be increased; and the productivity can be increased.

The pattern formation method and operations of the pattern formation method according to this embodiment will now be described using specific examples.

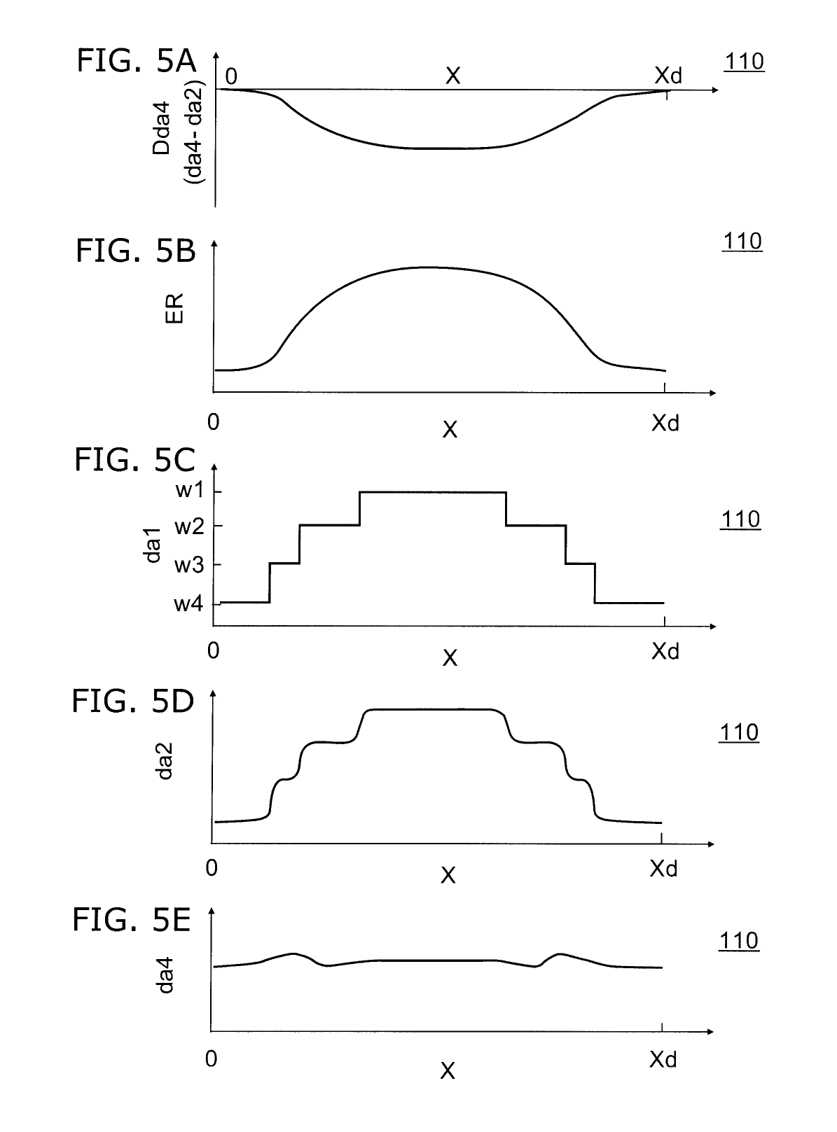

FIGS. 5A to 5E are graphs illustrating the pattern formation method according to the first embodiment.

Namely, FIG. 5A illustrates the data (a substrate protrusion width data Dda4) of the dimension of the pattern of the patterning film 28 after the patterning relating to the substrate protrusion width da4; FIG. 5B illustrates a characteristic of the patterning process; FIG. 5C illustrates a characteristic of the form recess width da1 of the form pattern 11 of the template 10 employed in the pattern formation method according to this embodiment; FIG. 5D illustrates a characteristic of the post post-processing protrusion width da2; and FIG. 5E illustrates a characteristic of the substrate protrusion width da4.

The substrate protrusion width data Dda4, an etching rate ER of the patterning process (corresponding to the etching amount of the substrate), the form recess width da1, the post post-processing protrusion width da2, and the substrate protrusion width da4 are plotted on the vertical axes of FIGS. 5A to 5E, respectively. A position x along the X axis direction is plotted on the horizontal axes of FIGS. 5A to 5E. The position where the position x is 0 is the position of one end of the substrate 20; and the position where the position x is Xd is the position at the other end of the substrate 20. In other words, these drawings illustrate the distributions of the characteristics recited above in the surface of the substrate 20. Herein, the substrate protrusion width data Dda4 is, for example, the substrate protrusion width da4 minus the post post-processing protrusion width da2. In other words, a case is described as one example of the data relating to the characteristics of the pattern configuration of the patterning film 28 after the patterning where the difference is used between the pattern configuration relating to the imprint material 30 after the post-processing and the pattern configuration of the patterning film 28 after the patterning film 28 is etched using the imprint material 30 as a mask.

As illustrated in FIG. 5A, the substrate protrusion width data Dda4 is not constant along the X axis direction in this specific example. For example, at the peripheral portion of the substrate 20 (the portion proximal to where the position x is 0 and the portion proximal to where the position x is the position xd), the absolute value of the substrate protrusion width data Dda4 is small and the substrate protrusion width da4 of the substrate 20 has a relatively good match with the post post-processing protrusion width da2 of the imprint material 30 after the post-processing. However, at the central portion of the substrate 20, the absolute value of the substrate protrusion width data Dda4 is large and the substrate protrusion width da4 of the substrate 20 is much smaller than the post post-processing protrusion width da2 of the imprint material 30 after the post-processing. The difference between the substrate protrusion width da4 and the post post-processing protrusion width da2 is small at the peripheral portion; and the difference between the substrate protrusion width da4 and the post post-processing protrusion width da2 is large at the central portion.

Such substrate protrusion width data Dda4 is based on data relating to, for example, a patterning process implemented in the past. In other words, the substrate protrusion width data Dda4 is based on experimental data implemented prior to implementing the pattern formation method according to this embodiment and/or various data derived based on theory. In such a case, data relating to an apparatus having specifications similar to those of the transfer unit 50 (which may include the post-processing unit 60) and the patterning unit 90 used in the pattern formation method may be used; and data relating to an apparatus having specifications different from those of the transfer unit 50 (which may include the post-processing unit 60) and the patterning unit 90 used in the pattern formation method, that is, data applicable to the pattern formation method, may be used.

Thus, the substrate protrusion width data Dda4 is not constant in the X-Y plane (in this example, the direction along the X axis direction).

As illustrated in FIG. 5B, the etching rate ER of the patterning process is, for example, low at the peripheral portion of the substrate 20 and high at the central portion of the substrate 20. Thus, the etching rate ER fluctuates in the X-Y plane (in this example, the direction along the X axis direction) due to the effects of various characteristics such as the characteristics of the patterning unit 90 as an apparatus and differences of the etching resistance of the imprint material 30 in the surface.

Thus, the etching rate ER fluctuates in the surface; and as a result, the substrate protrusion width data Dda4 fluctuates in the surface. In some cases, it is not easy to make the etching rate ER and the substrate protrusion width data Dda4 constant in the surface.

In such a case, in the pattern formation method according to this embodiment, the transfer process conditions are set to compensate such fluctuations.

For example, as illustrated in FIG. 5C, the form recess width da1 of the form pattern 11 is modified in different regions along the X axis direction. For example, the form recess width da1 is a smallest width w4 at the peripheral portion of the substrate 20; the form recess width da1 on the inner side thereof is a width w3 larger than the width w4; the form recess width da1 on the inner side thereof is a width w2 larger than the width w3; and the form recess width da1 at the central portion is a largest width w1.

In other words, different form patterns 11 are transferred onto the imprint material 30 in the surface of the substrate 20 by using multiple templates 10 in which different form patterns 11 having different form recess widths da1 are provided. In other words, the transfer process (step S110) is implemented.

Thereby, the post-transfer protrusion width da3 is not constant in the surface of the substrate 20 (e.g., the X axis direction) and is small at the peripheral portion and large at the central portion.

In the case where, for example, the characteristics of the post-processing (step S120) are constant in the surface of the substrate 20 (e.g., the X axis direction), the post post-processing protrusion width da2 is not constant in the surface of the substrate 20 (e.g., the X axis direction) and is small at the peripheral portion and large at the central portion following the changes of the post-transfer protrusion width da3 as illustrated in FIG. 5D.

Then, after the subsequent patterning process (step S130), for example, the distribution in the surface of the etching rate ER cancels with the distribution in the surface of the post post-processing protrusion width da2; and the substrate protrusion width da4 is substantially constant as illustrated in FIG. 5E.

Thus, in the pattern formation method according to this embodiment, the fluctuation of the patterning process also can be considered to provide a uniform pattern dimension in the surface after the patterning.

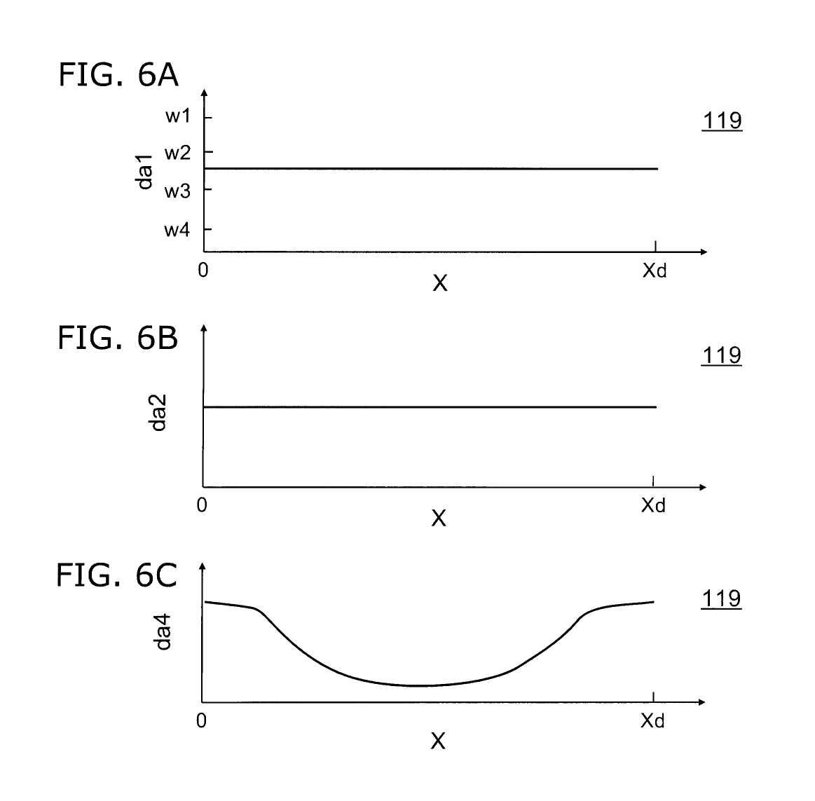

FIGS. 6A to 6C are graphs illustrating a pattern formation method of a comparative example.

Namely, FIG. 6A illustrates a characteristic of the form recess width da1 of the form pattern 11 of the template 10 employed in the pattern formation method of the comparative example; FIG. 6B illustrates a characteristic of the post post-processing protrusion width da2; and FIG. 6C illustrates a characteristic of the substrate protrusion width da4. The form recess width da1, the post post-processing protrusion width da2, and the substrate protrusion width da4 are plotted on the vertical axes of FIGS. 6A to 6C, respectively. The position x along the X axis direction is plotted on the horizontal axes of FIGS. 6A to 6C.

In the pattern formation method of the comparative example as illustrated in FIG. 6A, the form recess width da1 is constant in the surface of the substrate 20. In other words, in the comparative example, the transferring onto the imprint material 30 is performed using the template 10 having the same form recess width da1.

Thereby, the post-transfer protrusion width da3 is uniform in the surface. For example, by employing a method such as the method discussed in JP-A 2007-73939 (Kokai), the post-transfer protrusion width da3 can be uniform in the surface by controlling the positional relationship (the disposition) of the template 10 and the substrate 20 and the irradiation amount of the light 55L based on measurement information from measuring a physical quantity of the state of the imprint material 30 occurring due to the light irradiation of the transfer process.

Then, for example, post-processing is performed subsequently. Then, in the case where, for example, the characteristics of the post-processing are constant in the surface of the substrate 20 (e.g., the X axis direction), the post post-processing protrusion width da2 is uniform in the surface as illustrated in FIG. 6C.

However, as described in regard to FIGS. 5A and 5B, in the case where, for example, the etching rate ER is nonuniform in the surface in the patterning process and the substrate protrusion width data Dda4 fluctuates in the surface, at least one selected from the dimension and the shape of the substrate protrusion 24a is undesirably nonuniform in the surface in the case where the post post-processing protrusion width da2 is constant.

In other words, as illustrated in FIG. 6C, the substrate protrusion width da4 undesirably is large at the peripheral portion and small at the central portion.

Thus, in the pattern formation method of the comparative example, even in the cases where, for example, the light irradiation conditions of the transfer process are controlled to match the dimension and the shape of the post-transfer protrusion 23a to the desired specifications and, for example, the light irradiation conditions of the post-processing are controlled to match the dimension and the shape of the post post-processing protrusion 22a to the desired specifications and a uniform post post-processing protrusion width da1 in the surface is thereby obtained, the characteristics of the patterning process are not considered. Therefore, as a result, the substrate protrusion width da4 cannot be uniform in the surface. In other words, it is difficult to control the dimension and the shape of the substrate protrusion 24a to have the desired values.

Conversely, according to the pattern formation method according to this embodiment, the dimension and the shape of the substrate protrusion 24a can have the desired specifications by controlling the conditions of the transfer process (in this example, the form recess width da1 of the form pattern 11 of the template 10 being used) based on data (e.g., the substrate protrusion width data Dda4) relating to at least one selected from the dimension and the shape of the pattern configuration of the patterning film 28 after the patterning. In other words, in this example, the substrate protrusion width da4 can be uniform in the surface.

When a pattern formation method using photolithography is used instead of nanoimprinting, the configuration of openings of an exposure mask is transferred onto a photosensitive resist by, for example, irradiating light onto the resist via the exposure mask and developing. In such a case, the specifications of the openings of the exposure mask are constant, that is, one type of exposure mask is used when forming resists having the same configuration.

Conversely, in the pattern formation method of the nanoimprinting according to this embodiment, the multiple templates 10 having different specifications (e.g., the form recess width da1 recited above) in the surface of the substrate 20 are used when forming patterns (the pattern of the imprint material 30) having the same configuration. Thus, the transfer process is implemented and the patterning is performed by changing the template 10 in the surface of the substrate 20 or by changing the material pm0 of the imprint material 30, the coating amount of the imprint material 30, the light irradiation amount li0, the heat amount, etc., described below.

Although the description recited above relates to the characteristics along the X axis direction to simplify the description, similar effects may be obtained by performing similar controls relating to the Y axis direction.

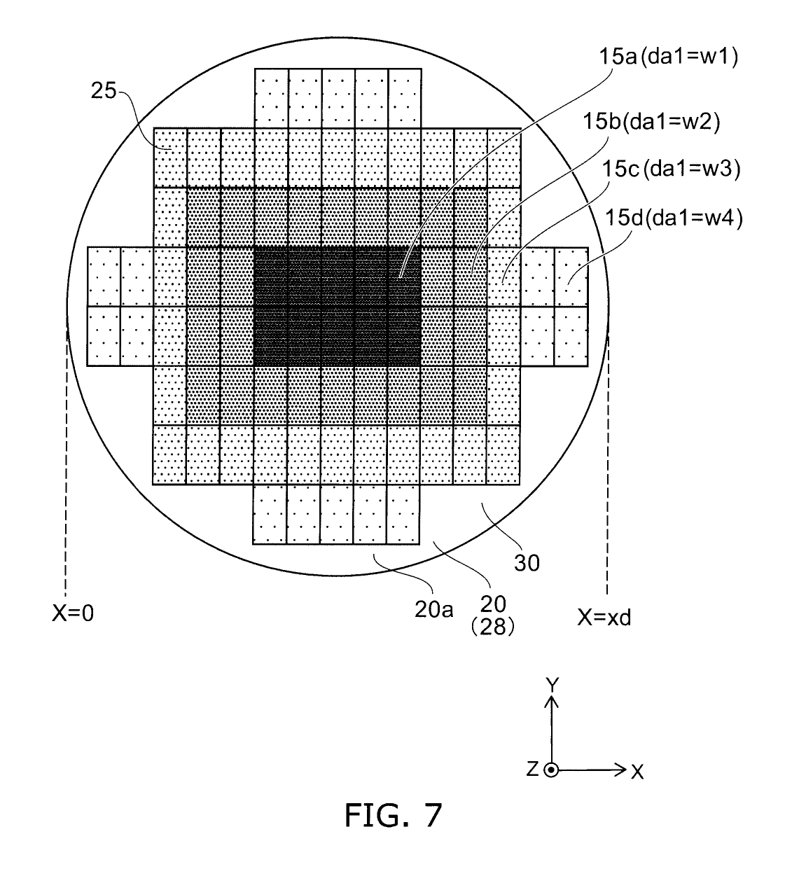

FIG. 7 is a schematic plan view illustrating the pattern formation method according to the first embodiment.

Namely, FIG. 7 is a plan view of the substrate 20 as viewed from the Z axis direction.

As illustrated in FIG. 7, the substrate 20 (the patterning film 28) has multiple regions 25 in the X-Y plane.

For example, the transferring in the central portion of the multiple regions 25 is performed using a first template 15a. The form recess width da1 of the form pattern 11 of the first template 15a is the width w1. The transferring in the region outside the central portion is performed using a second template 15b. The form recess width da1 of the form pattern 11 of the second template 15b is the width w2. The transferring in the region on the outer side thereof is performed using a third template 15c. The form recess width da1 of the form pattern 11 of the third template 15c is the width w3. Further, the transferring in the region on the outer side thereof is performed using a fourth template 15d. The form recess width da1 of the form pattern 11 of the fourth template 15d is the width w4. Here, for example, the width w3 is larger than the width w4; the width w2 is larger than the width w3; and the width w1 is larger than the width w2.

Thus, the form recess width da1 can be changed in both the X axis direction and the Y axis direction.

Although the case is described above where the form recess width da1 is determined based on data relating to at least one selected from the dimension and the shape of the pattern of the patterning film 28 after the patterning process, it is sufficient to determine at least one selected from a dimension (e.g., the form depth ta1, the form recess width da1, and the form protrusion width db1) of the form pattern 11, a shape (the form bottom angle θt1 and the form apical angle θb1) of the form pattern 11, the material pm0 of the imprint material 30, the coating amount of the imprint material 30, the light irradiation amount li0 applied to the imprint material 30 in a state of the template 10 contacting the imprint material 30, and the heat amount applied to the imprint material 30 in a state of the template 10 contacting the imprint material 30 based on the data.

The coating amount per unit surface area, for example, may be used as the coating amount of the imprint material 30. In such a case, the coating amount of the imprint material 30 may be taken as the thickness (the imprint material thickness mt0, e.g., the average thickness) of the imprint material 30 after the coating. The case is described hereinbelow where the imprint material thickness mt0 (the average thickness) is used as the coating amount of the imprint material 30.

By changing at least one selected from the dimension and the shape (e.g., the form depth ta1, the form recess width da1, the form protrusion width db1, the form bottom angle θt1, and the form apical angle θb1) of the form pattern 11, the dimension and the shape of the pattern configuration of the imprint material 30 after the transferring can be controlled. As a result, the dimension and the shape of the pattern configuration of the patterning film 28 after the patterning can be controlled.

By changing the material pm0 of the imprint material 30, not only can, for example, the pattern dimension and shape of the imprint material 30 after the transferring be controlled, but also the etching rates ER of the imprint material 30 of the post-processing process and the patterning process can be controlled. For example, the dimension and the shape of the imprint material 30 after the transferring and after the post-processing can have the desired values by changing the imprint material 30 from a material having a high etching resistance to a material having a low etching resistance in the surface of the substrate 20 when performing the transferring. For example, materials of different material types, materials having different molecular weights, and materials having different photoreactivities and the like may be used as the material pm0 of the imprint material 30. The imprint material 30 of different materials can be provided in the surface of the patterning film 28 of the substrate 20 by, for example, using an inkjet and the like.

By changing the coating amount of the imprint material 30 (e.g., the imprint material thickness mt0) in, for example, the surface, the pattern dimension and shape of the imprint material 30 after the post-processing can be controlled and the dimension and the shape of the pattern configuration of the patterning film 28 after the patterning can be controlled.

By changing at least one selected from the light irradiation amount li0 and the heat amount applied to the imprint material 30 in a state of the template 10 contacting the imprint material 30 in, for example, the surface, the property of the imprint material 30 can be changed and the etching rate ER of the imprint material 30 can be changed in the surface. Thereby, for example, the pattern dimension and shape of the imprint material 30 after the post-processing can be controlled. As a result, the dimension and the shape of the pattern configuration of the patterning film 28 after the patterning can be controlled.

In some cases, the condition determined in the transfer process (step S110) based on the data relating to at least one selected from the dimension and the shape of the patterning film 28 after the patterning may further include the thickness of the residual film recited above (i.e., the post-transfer recess thickness tb3). For example, by changing the thickness of the residual film, for example, the reduction amount (i.e., the etching amount ea0) of the film thickness of the post-processing process changes. Thereby, the pattern dimension and shape of the imprint material 30 after the post-processing can be controlled; and the dimension and the shape of the pattern configuration of the patterning film 28 after the patterning can be controlled. Even in the case where the post-processing is not performed, the dimension and the shape of the pattern configuration of the patterning film 28 after the patterning can be controlled by changing the thickness of the residual film.

Two or more selected from the dimension of the form pattern 11, the shape of the form pattern 11, the material pm0 of the imprint material 30, the coating amount of the imprint material 30 (e.g., the imprint material thickness mt0), the light irradiation amount 110, the heat amount, and the thickness of the residual film recited above may be changed simultaneously.

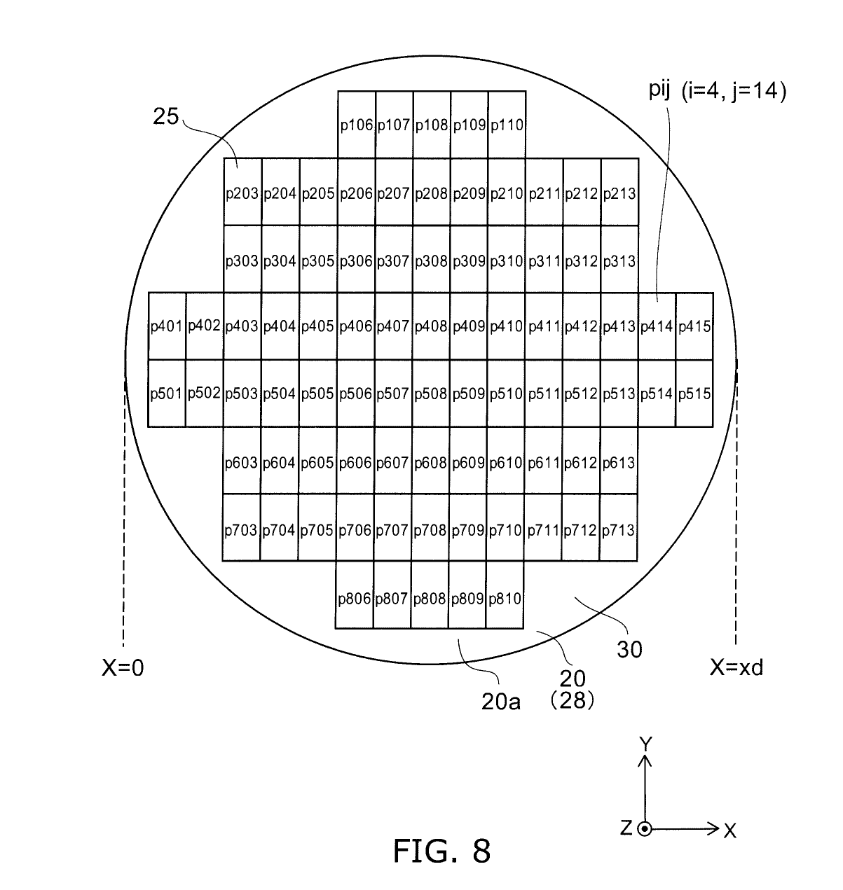

FIG. 8 is a schematic plan view illustrating the pattern formation method according to the first embodiment.

Namely, FIG. 8 is a plan view of the substrate 20 as viewed from the Z axis direction.

As illustrated in FIG. 8, the substrate 20 (the patterning film 28) has the multiple regions 25 in the X-Y plane. The positions of the multiple regions 25 are referred to by positions pij. Here, in this specific example, i is an integer from 1 to 8 and j is an integer from 1 to 15. Here, the position p414 refers to the 4th i and the 14th j position.

The dimension of the form pattern 11, the shape of the form pattern 11, the material pm0 of the imprint material 30, the coating amount of the imprint material 30 (e.g., the imprint material thickness mt0), the light irradiation amount 110, and the heat amount of such multiple regions 25 (the positions pij) may be determined independently from each other. In this specific example, the thickness of the residual film also may be determined.

The data relating to each of the dimension of the form pattern 11, the shape of the form pattern 11, the material of the imprint material 30, the coating amount of the imprint material 30 (e.g., the imprint material thickness mt0), the light irradiation amount 110, the heat amount, and the thickness of the residual film are stored, for example, in the data storage unit 70 illustrated in FIG. 2.

As illustrated in FIG. 2, the data storage unit 70 includes the first data storage unit 71 that stores data relating to the dimension and the shape of the form pattern 11, the second data storage unit 72 that stores data relating to the characteristics of the material pm0 of the imprint material 30, the third data storage unit 73 that stores data relating to the characteristics relating to the coating amount of the imprint material 30 (e.g., the imprint material thickness mt0), the fourth data storage unit 74 that stores data relating to at least one selected from the light irradiation amount li0 and the heat amount, the fifth data storage unit 75 that stores data relating to the thickness of the residual film, and the sixth data storage unit 76 that stores data relating to the etching amount (e.g., the etching rate ER) of the patterning film 28 of the patterning process.

The first data storage unit 71 stores data relating to the relationship between at least one selected from the dimension and the shape of the form pattern 11 and at least one selected from the dimension and the shape of the pattern of the imprint material 30 after the transferring and template separation, after the post-processing, and/or after the patterning.

The second data storage unit 72 stores data relating to the relationship between the characteristics of the material pm0 of the imprint material 30 (including at least one selected from characteristics such as material type, composition, molecular weight, product name, lot, etc.) and at least one selected from the dimension and the shape of the pattern of the imprint material 30 after the transferring and template separation, after the post-processing, and/or after the patterning.

The third data storage unit 73 stores data relating to the relationship between the coating amount of the imprint material 30 (e.g., the imprint material thickness mt0) and at least one selected from the dimension and the shape of the pattern of the imprint material 30 after the transferring and template separation, after the post-processing, and/or after the patterning.

The fourth data storage unit 74 stores data relating to the relationship between at least one selected from the light irradiation amount 110 and the heat amount applied to the imprint material 30 and at least one selected from the dimension and the shape of the pattern of the imprint material 30 after the transferring and template separation, after the post-processing, and/or after the patterning.

The fifth data storage unit 75 stores data relating to the relationship between the thickness of the residual film and at least one selected from the dimension and the shape of the pattern of the imprint material 30 after the post-processing and/or after the patterning. The fifth data storage unit 75 may further store data relating to the post-processing and may further include, for example, data relating to the processing characteristics of the post-processing unit 60 (e.g., fluctuation in the surface of the etching amount ea0, etc.).

The sixth data storage unit 76 stores data relating to the relationship between, for example, the etching amount (including, for example, the distribution in the surface) of the patterning film 28 of the patterning process and at least one selected from the dimension and the shape of the pattern of the imprint material 30 after the transferring and template separation and/or after the post-processing.

The data storage unit 70 may further include the seventh data storage unit 77 that stores characteristics of the transfer unit 50 (including, for example, characteristics of each of multiple transfer units in the case where multiple transfer units 50 are provided and characteristics of the accessory parts and the like used) and the characteristics of the post-processing unit 60 (including, for example, the characteristics of each of multiple post-processing units in the case where multiple post-processing units 60 are provided and characteristics of accessory parts and the like used).

The data storage unit 70 may include the eighth data storage unit 78 that stores data relating to various characteristics between the multiple substrates 20, data relating to various characteristics between lots of the substrates 20, etc.

The eighth data storage unit 78 may store data relating to the characteristic fluctuations focused on time (e.g., periodicity and the like of various characteristic fluctuations over durations of days, weeks, months, etc.) relating to, for example, the transfer and template separation process and the post-processing process.

The data storage unit 70 may further include a storage unit that stores characteristics relating to the dimension and the shape of the pattern after the transferring and template separation and after the post-processing relating to the patterning film 28 including the material quality of the substrate 20 and the patterning film 28, characteristics of the surface of particularly the patterning film 28, etc., and a storage unit that stores data relating to peripheral conditions such as the storage conditions of direct materials, indirect materials, transfer members, and components that are used.

Such characteristics of the transfer unit 50, characteristics of the post-processing unit 60, various characteristics between the substrates 20 and between lots, characteristics due to the types of the substrate 20 and the patterning film 28, and characteristics relating to the peripheral conditions may be considered to be part of the characteristics relating to the dimension and the shape of the form pattern 11, the material of the imprint material 30, the coating amount of the imprint material 30, the light irradiation amount and the heat amount, the thickness of the residual film, and the etching amount of the patterning process; and the data thereof also may be stored in the first to sixth data storage units 71 to 76.

Thus, each of, for example, the dimension of the form pattern 11, the shape of the form pattern 11, the material pm0 of the imprint material 30, the coating amount of the imprint material 30 (e.g., the imprint material thickness mt0), the light irradiation amount 110, the heat amount, the thickness of the residual film, etc., are determined as conditions relating to the transfer process in the multiple regions 25 (the positions pij) recited above. The data storage unit 70 may further include the ninth data storage unit 79 that stores a condition map d79 relating to the conditions of each of the multiple regions 25 (the positions pij).

The data storage unit 70 of this specific example further includes a calculation unit 70c that extracts or calculates the conditions such as the dimension of the form pattern 11, the shape of the form pattern 11, the material pm0 of the imprint material 30, the coating amount of the imprint material 30 (e.g., the imprint material thickness mt0), the light irradiation amount li0, the heat amount, and the thickness of the residual film based on the various determined conditions. The calculation unit may be provided separately from the data storage unit 70 and may be provided inside the transfer unit 50, inside the post-processing unit 60, and inside the patterning unit 90.

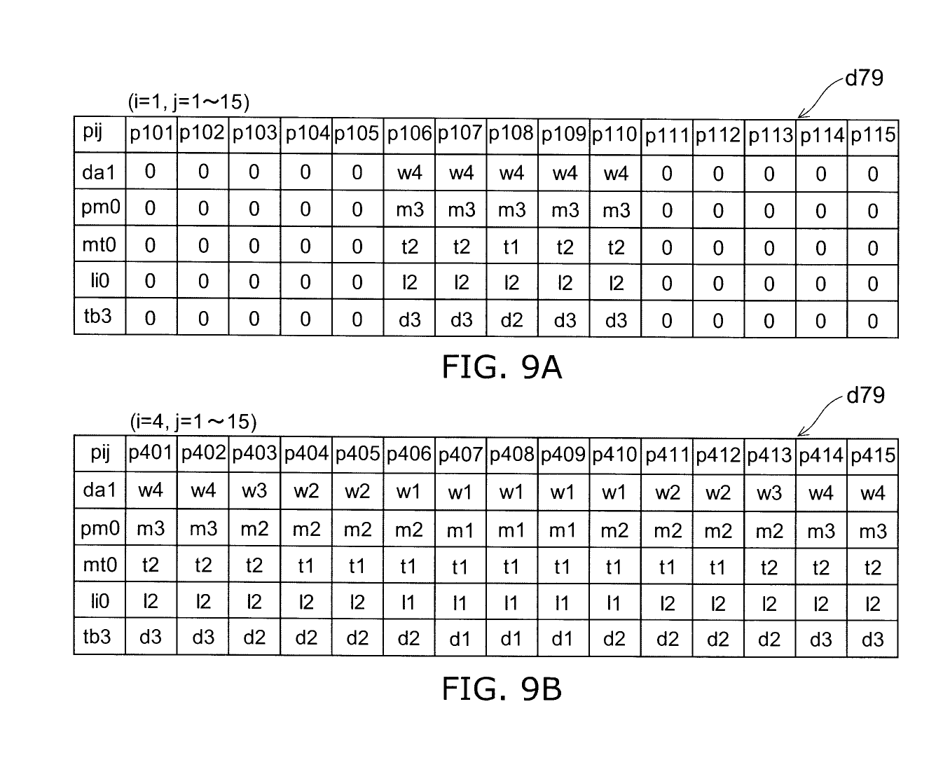

FIGS. 9A and 9B are schematic views illustrating the pattern formation method according to the first embodiment.

Namely, FIGS. 9A and 9B illustrate the dimension of the form pattern 11, the material pm0 of the imprint material 30, the coating amount of the imprint material 30 (e.g., the imprint material thickness mt0), the light irradiation amount 110, and the post-transfer recess thickness tb3 (i.e., the thickness of the residual film) for each of the positions p101 to the positions p115 and the positions p401 to the positions p415 of the multiple regions 25. Here, to simplify the description, the case is illustrated where the form recess width da1 is used as the dimension of the form pattern 11.

In other words, as illustrated in FIG. 9A, the form recess width da1 is the width w4 for the position p106 to the position p110. The regions corresponding to the position p101 to the position p105 and the position p111 to the position p115 are not provided in the substrate 20.

The material pm0 of the imprint material 30 is a material m3 for the position p106 to the position p110.

The coating amount of the imprint material 30 (in this example, the imprint material thickness mt0) is a thickness t2 for the positions p106, p107, p109, and p110; and the imprint material thickness mt0 is a thickness t1 for the position p108.

The light irradiation amount 110 of the light 55L during the transferring is a light amount 12 for the position p106 to the position p110.

The post-transfer recess thickness tb3, i.e., the thickness of the residual film, is a thickness d3 for the positions p106, p107, p109, and p110; and the post-transfer recess thickness tb3 is a thickness d2 for the position p108.

As illustrated in FIG. 9B, the form recess width da1 is the width w4 for the positions p401, p402, p414, and p415; the form recess width da1 is the width w3 for the positions p403 and p413; the form recess width da1 is the width w2 for the positions p404, p405, p411, and p412; and the form recess width da1 is the width w1 for the position p406 to the position p410.

The material m3 is used as the material pm0 of the imprint material 30 for the positions p401, p402, p414, and p415; a material m2 is used as the material pm0 of the imprint material 30 for the position p403 to the position p406 and the position p410 to the position p413; and a material m1 is used as the material pm0 of the imprint material 30 for the position p407 to the position p409.

The imprint material thickness mt0, i.e., the coating amount of the imprint material 30, is the thickness t2 for the position p401 to the position p403 and the position p413 to the position p415; and the imprint material thickness mt0 is the thickness t1 for the position p404 to the position p412.

The light irradiation amount li0 is the light amount l2 for the position p401 to the position p405 and the position p411 to the position p415; and the light irradiation amount li0 is a light amount l1 for the position p406 to the position p410.

The post-transfer recess thickness tb3, i.e., the thickness of the residual film, is the thickness d3 for the positions p401, p402, p414, and p415; the post-transfer recess thickness tb3 is the thickness d2 for the position p403 to the position p406 and the position p410 to the position p413; and the post-transfer recess thickness tb3 is a thickness d1 for the position p407 to the position p409.

Thus, the condition map d79 in which the conditions are stored is made for the multiple regions 25 (the positions pij) in the surface of the substrate 20.

Thus, each of the dimension of the form pattern 11, the shape of the form pattern 11, the material pm0 of the imprint material 30, the coating amount of the imprint material 30 (e.g., the imprint material thickness mt0), the light irradiation amount li0, the heat amount, and the thickness of the residual film (the post-transfer recess thickness tb3), and the like of the multiple regions 25 (the positions pij) in the surface of the substrate 20 can be changed and determined. Thereby, the pattern dimension and the pattern shape of the patterning film 28 after the patterning can be controlled with even better precision; and the pattern dimension and the pattern shape after the patterning can have the desired values with even better precision.

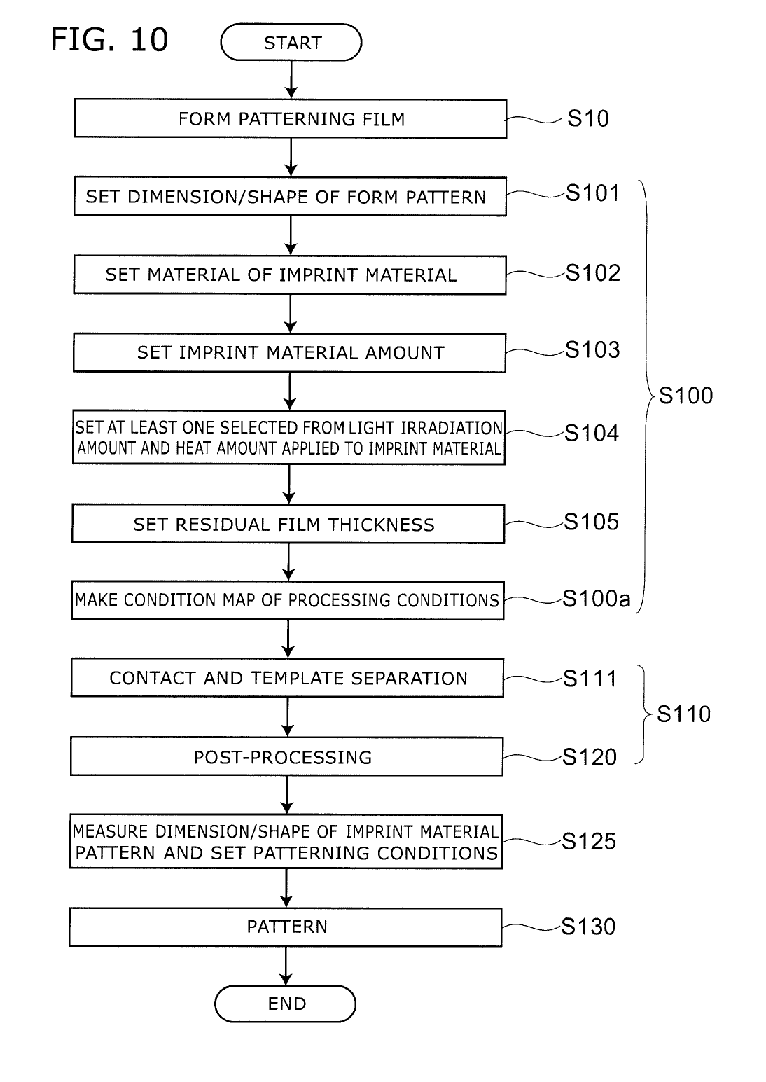

FIG. 10 is a flowchart illustrating one other pattern formation method according to the first embodiment.

In the one other pattern formation method according to this embodiment as illustrated in FIG. 10, at least one selected from the dimension and the shape of the form pattern 11 is set (step S101). For example, at least one selected from the post post-processing protrusion height ta2, the post post-processing protrusion width da1, the post post-processing recess width db2, the post post-processing apical angle θt2, and the post post-processing bottom angle θb2 relating to the form pattern 11 is set. For example, such values can be changed and set for different positions in the surface of the substrate 20. Then, the template 10 having such values is selected.

For example, the template 10, having the form pattern 11 such that the dimension and the shape of the pattern of the patterning film 28 after the patterning have the desired values, is selected based on the data stored in the first data storage unit 71 and the fifth data storage unit 75.

Then, the material pm0 of the imprint material 30 is set (step S102).

For example, the material pm0 is set such that the dimension and the shape of the pattern of the patterning film 28 after the patterning have the desired values based on the data stored in the second data storage unit 72 and the fifth data storage unit 75.

Then, the coating amount of the imprint material 30 (e.g., the imprint material thickness mt0) is set (step S103).

For example, the imprint material thickness mt0 is set such that the dimension and the shape of the pattern of the patterning film 28 after the patterning have the desired values based on the data stored in the third data storage unit 73 and the fifth data storage unit 75.

Then, at least one selected from the light irradiation amount li0 and the heat amount applied to the imprint material 30 is set (step S104).

For example, the light irradiation amount li0 is set such that the dimension and the shape of the pattern of the patterning film 28 after the patterning have the desired values based on the data stored in the fourth data storage unit 74 and the fifth data storage unit 75.

Then, the thickness of the residual film (the post-transfer recess thickness tb3) is set (step S105). For example, the strength when the template 10 and the substrate 20 are pressed together and the distance between the template 10 and the patterning film 28 are set.

For example, the thickness of the residual film is set such that the dimension and the shape of the pattern of the patterning film 28 after the patterning have the desired values based on the data stored in the fifth data storage unit 75.

The order of the steps S101 to S105 recited above is arbitrary; and the implementation may be simultaneous within the extent of technical feasibility. It is sufficient for at least one selected from step S101 to step S104 recited above to be implemented.

In other words, a condition including at least one selected from the dimension of the form pattern 11, the shape of the form pattern 11, the material pm0 of the imprint material 30, the coating amount of the imprint material 30 (e.g., the imprint material thickness mt0), the light irradiation amount li0 applied to the imprint material 30, and the heat amount applied to the imprint material 30 is determined (step S100).

Step S100 is implemented by, for example, the calculation unit 70c of the data storage unit 70. In other words, the calculation unit 70c extracts or calculates to determine at least one selected from the template 10, the material pm0 of the imprint material 30, the coating amount of the imprint material 30 (e.g., the imprint material thickness mt0), the light irradiation amount li0, and the heat amount such that at least one selected from the dimension and the shape of the pattern of the patterning film 28 after the patterning has the desired value.

Further, the condition map d79 is made (step S100a).

In other words, the condition map d79 of the conditions (e.g., the dimension of the form pattern 11, the shape of the form pattern 11, the material pm0 of the imprint material 30, the coating amount of the imprint material 30, e.g., the imprint material thickness mt0, the light irradiation amount li0, the heat amount, etc.) corresponding to the positions pij of the multiple regions 25 in the surface of the substrate 20 such as that illustrated in FIGS. 9A and 9B is made. The condition map d79 made in step S100a is stored in the ninth data storage unit 79. The making of the condition map d79 and the storing of the condition map d79 in the ninth data storage unit 79 can be performed by the calculation unit 70c.

The operations of the calculation unit 70c recited above may be implemented by a calculation unit provided separately from the data storage unit 70 and may be implemented by, for example, the transfer control unit 50c, the post-processing control unit 60c, and the patterning control unit 90c.

Although step S100 recited above is implemented after the forming of the patterning film (step S10) in this specific example, at least a portion of step S100 (at least a portion of step S101 to step S105 and step S101a) may be implemented simultaneously with step S10 or prior to step S10.

Using the determined conditions, the transferring (step S110) is performed and the patterning (step S130) is performed. The transferring (step S110) may include the transfer and template separation process (step S111) illustrated in FIGS. 4A to 4C and the post-processing process (step S120) illustrated in FIG. 4D.

For example, the operations of the transfer unit 50 (also including the post-processing unit 60) are implemented based on the conditions of the condition map d79 stored in the ninth data storage unit 79. Thereby, the pattern dimension and the pattern shape of the patterning film 28 after the patterning can have the desired values with good precision.

As illustrated in FIG. 10, the patterning conditions (e.g., the etching conditions) of the patterning process may be set (step S125) based on the results of measuring the dimension and the shape of the imprint material 30 after the post-processing.

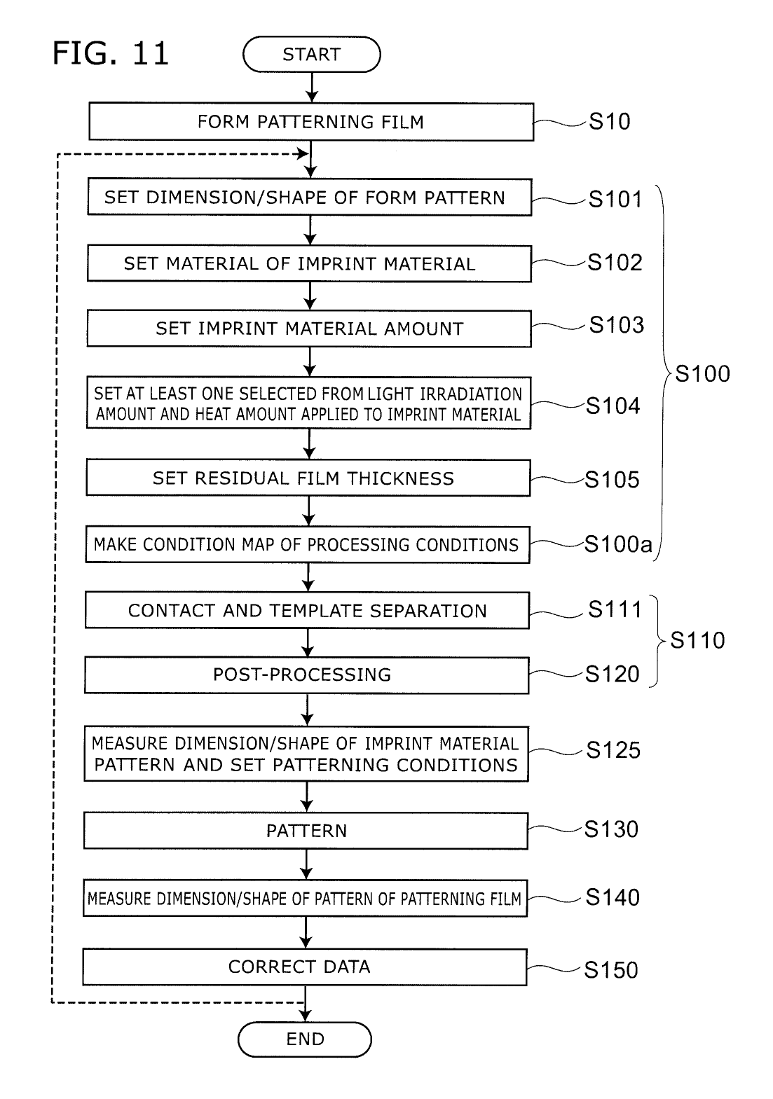

FIG. 11 is a flowchart illustrating yet one other pattern formation method according to the first embodiment.

In the yet one other pattern formation method according to this embodiment as illustrated in FIG. 11, the pattern formation method illustrated in FIG. 10 further includes measuring at least one selected from a dimension and a shape of the pattern of the patterning film 28 (step S140) after the patterning process (step S130).

Then, the data recited above relating to the at least one selected from the dimension and the shape of the pattern of the patterning film 28 after the patterning is corrected (step S150) based on the result of the measuring. For example, the various data stored in the data storage unit 70 is renewed.

Such data may include formulas of the relationships between the dimension and the shape of the pattern of the patterning film 28 after the patterning and at least one selected from the dimension of the form pattern 11, the shape of the form pattern 11, the material pm0 of the imprint material 30, the coating amount of the imprint material 30 (e.g., the imprint material thickness mt0), the light irradiation amount 110, and the heat amount relating to the transfer process.

In other words, the pattern formation system 110 may further include the measurement unit 80 that measures at least one selected from the dimension and the shape of the pattern of the patterning film 28 after the patterning process; and the data of the data storage unit 70 can be corrected based on the measurement result of the measurement unit 80.

Then, step S100, step S110, step S120, and step S130 are performed using the corrected and renewed data.

Thereby, the precision of the data relating to the at least one selected from the dimension and the shape of the pattern of the patterning film 28 after the patterning is increased by using the data measured each time; and the pattern dimension and the pattern shape of the patterning film 28 after the patterning can have the desired values with better precision.

Thus, in the pattern formation method according to this embodiment, conditions including, for example, at least one selected from the dimension of the form pattern 11, the shape of the form pattern 11, the material pm0 of the imprint material 30, the coating amount of the imprint material 30 (e.g., the imprint material thickness mt0), the light irradiation amount li0 applied to the imprint material 30, and the heat amount applied to the imprint material 30 are determined based on the data relating to at least one selected from the dimension and the shape of the pattern of the patterning film 28 after the patterning process; and at least one portion of the condition is modified in the surface of the substrate 20. In other words, the conditions recited above are modified between different regions in the major surface of the substrate 20.

However, the embodiments are not limited thereto. In other words, the conditions recited above may be changed between the substrates and between lots of the substrates.

### Second Embodiment

In this embodiment, the conditions relating to the transfer process are modified between the substrates and between the lots of the substrates.

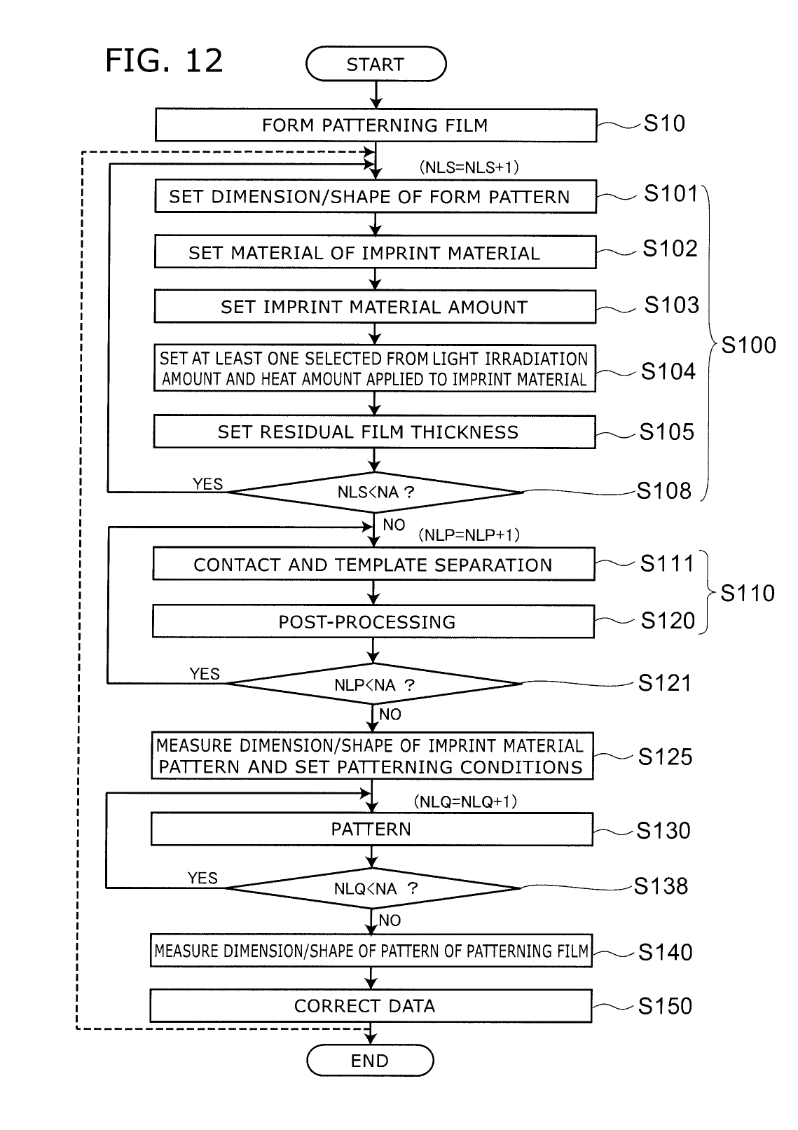

FIG. 12 is a flowchart illustrating the pattern formation method according to the second embodiment.

As illustrated in FIG. 12, an implementation number NLS is compared to a prescribed number NA (step S108) after implementing step S101 to step S105 on the substrate 20. In the case where the implementation number NLS is less than the prescribed number NA, the flow returns to step S101; and step S101 to step S105 are implemented repeatedly until the implementation number NLS reaches the prescribed number NA.

The prescribed number NA may be, for example, the number of the substrates 20 included in one cassette or the number of the substrates 20 included in one lot. Hereinbelow, the prescribed number NA is taken to be the number of the substrates 20 included in one cassette.

In other words, the conditions relating to the transfer process are determined for all of the substrates 20 included in one cassette. The conditions relating to the transfer process may be modified, for example, for the upper levels, the middle levels, and the lower levels of the cassette. For example, the temperature of the apparatus, the gas composition, the gas flow rate, the characteristics of the irradiated light, etc., may change between the upper levels, the middle levels, and the lower levels of the cassette; and at least one selected from the dimension and the shape of the pattern of the patterning film 28 after the patterning may change between the upper levels, the middle levels, and the lower levels of the cassette even in the case where patterns having the same specifications are formed on the substrates 20 disposed in the upper levels, the middle levels, and the lower levels of the cassette. In such a case, the conditions relating to the transfer process may be modified between the upper levels, the middle levels, and the lower levels of the cassette.

Although not illustrated in FIG. 12, the condition map d79 of the processing conditions may be made (step S100a). Thereby, different conditions are set for different positions in the surface of the substrate 20; and the data of such conditions is stored.

Then, after implementing step S110 (the transfer process) (which may include the post-processing process of step S120), an implementation number NLP is compared to the prescribed number NA (step S121). Then, in the case where the implementation number NLP is less than the prescribed number NA, the flow returns to step S110; and step S110 (and step S120) is implemented repeatedly until the implementation number NLP reaches the prescribed number NA. In other words, the transfer process is implemented for all of the substrates 20 included in the one cassette based on the conditions determined for each.

As necessary, the measuring of at least one selected from the dimension and the shape of the pattern of the imprint material 30 after the post-processing and the setting of the patterning conditions (the etching conditions, etc.) of the patterning process (step S125) may be performed.

Then, step S130 (the patterning process) is performed. After implementing step S130 (the patterning process), an implementation number NLQ is compared to the prescribed number NA (step S138). In the case where the implementation number NLQ is less than the prescribed number NA, the flow returns to step S130; and step S130 is implemented repeatedly until the implementation number NLQ reaches the prescribed number NA. In other words, the patterning is implemented for all of the substrates 20 included in the one cassette based on the conditions determined for each.

Subsequently, as necessary, the measuring of the dimension and the shape of the pattern of the patterning film 28 after the patterning may be performed (step S140) and the data may be corrected (step S150).

Thus, the conditions relating to the transfer process are changed, for example, between the multiple substrates 20 disposed in the one cassette. Thereby, the pattern dimension and the pattern shape of the patterning film 28 after the patterning can have the desired values with better precision.

Although the number of the substrates 20 contained in one cassette is used as the prescribed number NA in the description recited above, the embodiments are not limited thereto. The prescribed number NA is arbitrary and may be the number of the substrates 20 of one lot or the cumulative processing number for, for example, a constant interval (e.g., hours, days, weeks, months, etc.).

Thus, the conditions relating to the transfer process are determined based on the data relating to the at least one selected from the dimension and the shape of the pattern of the patterning film 28 after the patterning; and at least one portion of the conditions can be modified between the different regions in the major surface (in the surface) of the substrate 20, between the substrates, and/or between the lots of the substrates.

Thereby, the pattern dimension and the pattern shape of the patterning film 28 after the patterning can have the desired values with better precision.

Thereby, the performance improvement and the downscaling of electronic devices (including semiconductor devices) manufactured using the pattern formation method and the pattern formation system 110 are easy; the yields can be increased; and the productivity can be increased.

The patterning process (step S130) recited above is not limited to the etching of the patterning film 28 and may include patterning that performs any processing of the patterning film 28 of the major surface 20a of the substrate 20 using the imprint material 30 including the transferred form pattern 11. In other words, in addition to the etching of the patterning film 28 using the imprint material 30 as a mask, the patterning process may include the implementation of processing such as light irradiation processing and plasma processing on the patterning film 28 using the imprint material 30 as a mask, forming a film on the patterning film 28 using the imprint material 30 as a lift-off resist, etc. Then, the conditions of the transfer process may be determined based on the data relating to the at least one selected from the dimension and the shape of the region where the processing is performed on the patterning film 28 after the patterning. The conditions of the transfer process may be determined based on the data relating to the at least one selected from the dimension and the shape of the film formed on the patterning film 28 after the patterning.

The pattern formation methods recited above can be applied to a method for manufacturing a semiconductor device.

In other words, the method for manufacturing the semiconductor device according to one other embodiment includes forming the patterning film 28 on the substrate 20. In such a case, at least one selected from the substrate 20 and the patterning film 28 includes a semiconductor. The forming of the patterning film corresponds to step S10 illustrated in FIG. 1.

Similarly to the method illustrated in FIG. 1, the method for manufacturing the semiconductor device further includes transferring the form pattern 11 provided on the template 10 onto the imprint material 30 coated on the patterning film 28 by bringing the template 10 into contact with the imprint material 30 (step S110) and performing patterning including etching the patterning film 28 using the imprint material 30 including the transferred form pattern 11 as a mask (step S130).

The transfer process is implemented using the conditions determined based on the data relating to at least one selected from the dimension and the shape of the pattern of the patterning film 28 after the patterning.

Thereby, a semiconductor device can be obtained with the pattern dimension and the pattern shape of the desired values after the patterning.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the invention is not limited to these specific examples. For example, one skilled in the art may similarly practice the invention by appropriately selecting specific configurations of components such as templates, substrates, patterning films, and imprint materials used in pattern formation methods, pattern formation systems, and methods for manufacturing semiconductor devices and transfer units, post-processing units, patterning units, data storage units, and measurement units included in pattern formation systems from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all pattern formation methods, pattern formation systems, and methods for manufacturing semiconductor devices practicable by an appropriate design modification by one skilled in the art based on the pattern formation methods, the pattern formation systems, and the methods for manufacturing semiconductor devices described above as exemplary embodiments of the invention also are within the scope of the invention to the extent that the purport of the invention is included.

Furthermore, various modifications and alterations within the spirit of the invention will be readily apparent to those skilled in the art. All such modifications and alterations should therefore be seen as within the scope of the invention. For example, additions, deletions, or design modifications of components or additions, omissions, or condition modifications of processes appropriately made by one skilled in the art in regard to the exemplary embodiments described above are within the scope of the invention to the extent that the purport of the invention is included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A pattern formation method, comprising:
forming a patterning film on a substrate;
transferring a form pattern provided on a template onto an imprint material by bringing the template into contact with the imprint material, the imprint material being coated on the patterning film; and
performing patterning including etching the patterning film using the imprint material including the transferred form pattern as a mask,
the transferring being implemented using a condition determined based on data relating to at least one selected from a dimension and a shape of a pattern of the patterning film after the patterning.

2. The method according to claim 1, wherein the condition includes at least one selected from:
a dimension of the form pattern;
a shape of the form pattern;
a material of the imprint material;
a coating amount of the imprint material;
a light irradiation amount applied to the imprint material in a state of the template contacting the imprint material; and
a heat amount applied to the imprint material in a state of the template contacting the imprint material.

3. The method according to claim 2, wherein the condition further includes a thickness of a residual film of the imprint material including the transferred form pattern, the residual film being a portion of the imprint material between the patterning film and a protrusion of the form pattern.

4. The method according to claim 1, wherein the transferring includes performing post-processing to expose a portion of the patterning film by removing a residual film of the imprint material including the transferred form pattern, the residual film being a portion of the imprint material between the patterning film and a protrusion of the form pattern.

5. The method according to claim 1, wherein at least one portion of the condition is modified
between different regions in a major surface of the substrate,
between the substrates, and/or
between lots of the substrates.

6. The method according to claim 1, further comprising:
measuring at least one selected from a dimension and a shape of a pattern of the patterning film after the patterning; and
correcting the data based on a result of the measuring.

7. The method according to claim 1, wherein the transferring includes a processing implemented on a first region in a major surface of the substrate using a first template having a first form pattern and a processing implemented on a second region in the major surface of the substrate different from the first region using a second template having a second form pattern different from the first form pattern.

8. The method according to claim 1, wherein the transferring includes at least one selected from:
setting a dimension of the form pattern;
setting a shape of the form pattern;
setting a material of the imprint material;
setting a coating amount of the imprint material;
setting a light irradiation amount applied to the imprint material in a state of the template contacting the imprint material; and
setting a heat amount applied to the imprint material in a state of the template contacting the imprint material.

9. The method according to claim 8, wherein the transferring further includes setting a thickness of a residual film of the imprint material including the transferred form pattern, the residual film being a portion of the imprint material between the patterning film and a protrusion of the form pattern.

10. The method according to claim 8, wherein the transferring further includes making a condition map including at least one selected from the dimension of the form pattern, the shape of the form pattern, the material of the imprint material, the coating amount of the imprint material, the light irradiation amount, and the heat amount of the setting according to positions of a plurality of regions in a surface of the substrate.

11. The method according to claim 1, wherein at least one portion of the condition is modified between the substrates stored at different positions in a cassette storing the substrates.

12. A pattern formation system, comprising:
a transfer unit transferring a form pattern of a template onto an imprint material by bringing the template into contact with the imprint material, the imprint material being coated on a patterning film of a substrate;
a patterning unit performing patterning including etching the patterning film using the imprint material including the transferred form pattern as a mask; and
a data storage unit storing data relating to at least one selected from a dimension and a shape of a pattern of the patterning film after the patterning,
at least one portion of a condition of processing of the transfer unit being determined based on the data stored in the data storage unit.

13. The system according to claim 12, wherein the at least one portion of the condition includes at least one selected from:
a dimension of the form pattern;
a shape of the form pattern;
a material of the imprint material;
a coating amount of the imprint material;
a light irradiation amount applied to the imprint material in a state of the template contacting the imprint material; and
a heat amount applied to the imprint material in a state of the template contacting the imprint material.

14. The system according to claim 13, wherein the at least one portion of the condition further includes a thickness of a residual film of the imprint material including the transferred form pattern, the residual film being a portion of the imprint material between the patterning film and a protrusion of the form pattern.

15. The system according to claim 12, wherein the transfer unit includes a post-processing unit exposing a portion of the patterning film by removing a residual film of the imprint material including the transferred form pattern, the residual film being a portion of the imprint material between the patterning film and a protrusion of the form pattern.

16. The system according to claim 15, wherein the post-processing unit includes a dry etching apparatus including a plasma generation unit.

17. The system according to claim 12, wherein the at least one portion of the condition is modified
between different regions in a major surface of the substrate,
between the substrates, and/or
between lots of the substrates.

18. The system according to claim 12, further comprising a measurement unit measuring at least one selected from a dimension and a shape of a pattern of the patterning film after the patterning,
the data of the data storage unit being corrected based on a measurement result of the measurement unit.

19. The system according to claim 12, wherein the patterning unit includes a dry etching apparatus including a plasma generation unit.

20. A method for manufacturing a semiconductor device, comprising:
forming a patterning film on a substrate, at least one selected from the substrate and the patterning film including a semiconductor;
transferring a form pattern provided on a template onto an imprint material by bringing the template into contact with the imprint material, the imprint material being coated on the patterning film; and
performing patterning including etching of the patterning film using the imprint material including the transferred form pattern as a mask,
the transferring being implemented using a condition determined based on data relating to at least one selected from a dimension and a shape of a pattern of the patterning film after the patterning.
